(19) United States
(12) Patent Application Publication
(10) Pub. No.: US 2021/0123636 A1
(43) Pub. Date: Apr. 29, 2021

(54) ELECTRICAL EQUIPMENT COOLING SYSTEM FOR VEHICLE

(71) Applicant: Hanon Systems, Daejeon (KR)

(72) Inventors: Hae Jun LEE, Daejeon (KR); Hyeong Kyu JIN, Daejeon (KR); Seong Hun KIM, Daejeon (KR)

(21) Appl. No.: 17/053,137

(22) PCT Filed: May 3, 2019
(86) PCT No.: PCT/KR2019/005372

§ 371 Date: Nov. 5, 2020

(30) Foreign Application Priority Data
Jun. 20, 2018 (KR) 10-2018-0071019

(51) Int. Cl. F25B 1/00; H05K 7/20

(52) U.S. Cl. CPC F25B 1/005; H05K 7/20318; F25B 2339/047; H05K 7/20209; H05K 7/20172; H05K 7/20872

(57) ABSTRACT

The present disclosure relates to an electrical equipment cooling system for a vehicle. For this, an embodiment relates to an electrical equipment cooling system for a vehicle, in which a condenser 300 and a fan unit 400 are disposed to be tilted with respect to a direction in which a running wind is inhaled.

### BACKGROUND OF THE DISCLOSURE

### Field of the Disclosure

Exemplary embodiments of the present disclosure are to seek cooling of electrical equipment provided in a self-driving car, and more particularly to an electrical equipment cooling system for a vehicle.

### Description of the Related Art

In general, vehicles mounted with power trains being called hybrid systems, in each of which a combination of an internal combustion engine (gasoline engine or diesel engine) and an electric motor is formed, have been developed and commercialized.

In order to drive the electric motor being used for driving, the vehicle is mounted with electrical devices, for example, a power storage device, such as a secondary battery or a capacitor, and a power conversion device, such as an inverter or a DC/DC converter.

The secondary battery is charged or discharged through a chemical reaction including heat generation, and thus it requires cooling. Further, the inverter and the DC/DC converter are provided with power elements that generate heat, and thus they require cooling. In general, the electrical device generates Joule heat while current flows through a power line, and thus it requires cooling.

The electrical device may be disposed between a vehicle rear seat and a trunk. The electrical device is disposed in a duct type casing that forms an air passage. A cooling fan that generates a cooling wind to cool the electrical device is disposed between the electrical device and the rear seat on an intake upstream side of the electrical device in the casing.

An upstream end portion of the casing communicates with a vehicle interior, and as an example, the upstream end portion of the casing is opened from a rear package tray, and the electrical device is cooled by air in the vehicle interior.

The inverter and the DC/DC converter may be integrated in the electrical device that is called a power control unit (PCU), and may be mounted on the vehicle. The PCU may also be disposed between the vehicle rear seat and the trunk as the electrical device.

A hybrid vehicle should be mounted with such an electrical device together with an engine. Japanese Patent Laid-Open Publication No. 2004-161058 discloses a battery cooling duct capable of surely releasing a hydrogen gas and so on, which may be possibly generated from a battery mounted on a vehicle, to an outside of the vehicle.

The battery cooling duct disclosed in the above-described publication is applied to the vehicle mounted with the battery, and it includes a communicating passage for communication between the battery and the interior of the vehicle and a gas retaining unit provided in the communicating passage.

According to the above-described battery duct, the hydrogen gas being generated from the battery can be temporarily stored in the gas retaining unit, and thus it is possible to reduce or prevent the gas from permeating into the vehicle interior.

Japanese Patent Laid-Open Publication No. 2005-186868 discloses a cooling device for a power storage device capable of suppressing influences exerted on the vehicle interior and pressure losses. The cooling device for the power storage device disclosed in the above-described publication includes an exhaust unit discharging air, which is heated through heat exchange by the power storage device, from the power storage device to the vehicle interior, and an exhaust fan exhausting the air heated through the heat exchange from the vehicle interior to an outside of the vehicle.

According to the above-described cooling device for the power storage device, the air heated through the heat exchange caused by the power storage device is exhausted from the power storage device to the vehicle interior. Thereafter, the air is exhausted from the vehicle interior to the outside of the vehicle by the exhaust fan.

Even without additionally providing an exhaust duct for guiding the air from the power storage device to the outside of the vehicle to bypass the vehicle interior, it may be possible to discharge the air heated through the heat exchange to the outside of the vehicle. Accordingly, the influences exerted on the vehicle interior and the pressure losses can be suppressed.

In a vehicle mounted with devices disclosed in Japanese Patent Laid-Open Publication Nos. 2004-161058 and 2005-186868, a cooling wind intake port may be provided in a rear package tray in case that an electrical device mounted on a rear side of the vehicle is cooled by air in a vehicle interior.

However, if the intake port is provided in the rear package tray, the intake port may be located adjacent to a rear wind shield, and infrared rays of sunlight are radiated to increase the temperature of the air adjacent to the intake port. In this case, the temperature of the cooling wind is increased to cause the electrical device not to be efficiently cooled.

Recently, with the development of a self-driving car, an individual cooler of electrical equipment having a modularized structure is provided, and an example of the electrical equipment may be a standalone system provided with, for example, a lidar, a radar, various kinds of sensors, a CPU, and a GPU.

In the standalone system, an individual cooler is installed for cooling, and cooling is performed through blowing toward the electrical equipment. In this case, however, a separate air duct is required, and this may cause disadvantage in cost and design.

Further, since a cooling water line should always be located on the upper side of an electric part for air removal of the cooling water line, restrictions exist in the design of the cooling water line, and there is a problem in? that noise, which is generated due to the individual cooler located indoors, is increased.

### SUMMARY OF THE DISCLOSURE

The present disclosure provides a system for cooling electrical equipment for a vehicle, which can seek a stable cooling of electrical equipment provided in a self-driving car.

Other aspects and advantages of the present disclosure can be understood by the following description, and become apparent with reference to embodiments of the present disclosure. Also, it is obvious to those skilled in the art to which the present disclosure pertains that the aspects and advantages of the present disclosure can be realized by the means as claimed and combinations thereof.

In accordance with an embodiment of the present disclosure to achieve the above object, a cooling system for a vehicle includes an electric compressor 500 compressing and circulating a refrigerant; a condenser 300 condensing the compressed refrigerant; an expansion valve 700 throttling the condensed refrigerant; a chiller unit 800 performing heat exchange between the throttled refrigerant and a cooling water; and a fan unit 400 adjacently disposed in front of the condenser 300 and inhaling a running wind for condensing the compressed refrigerant, wherein the condenser 300 and the fan unit 400 are disposed to be tilted with respect to a direction in which the running wind is inhaled.

The condenser 300 is provided inside a casing 200 in which a vent grill 202 opened with a specific size to perform air movement is formed.

The casing 200 is formed in a cuboidal shape in which a length corresponding to a height b extends to be shorter than a length corresponding to a width a or a length corresponding to a depth c.

The cooling system includes a cooling water pipe 4 forming a loop that is branched from the chiller unit 800 and is recycled to the chiller unit 800 after passing through a cooling object 100 in order to cool the cooling object 100 composed of a plurality of electrical equipment 102 being self-heated with a specific temperature and providing a passage through which the cooling water moves.

The electrical equipment 102 is provided in a self-driving car 10.

The casing 200 is provided with a bottom plate 910 located on an inner bottom surface of the casing 200 and a stand 920 having one end connected to the bottom plate 910 and the other ends extending toward the condenser 300 with different lengths, wherein the condenser 300 is disposed to be tilted by the stand 920.

The vent grill 202 includes a first vent grill 202a opened on an upper surface of the casing 200; a second vent grill 910b opened on the bottom plate 910, and a third vent grill 202c opened on a front surface of the casing 200.

The first vent grill 202a and the second vent grill 910b are formed to face each other with a corresponding size.

The second vent grill 910b is formed to be larger than an opening size of the first vent grill 202a.

The condenser 300 is located to face the fan unit 400, and has a corresponding size.

The cooling system includes a first gap space Si formed in an upwardly spaced location between an inner bottom surface of the casing 200 and the condenser 300, and a second gap space S2 formed between an inner upper surface of the casing 200 and the fan unit 400.

An upper surface of the casing 200 is located adjacent to an extractor grill provided in the vehicle.

The electrical equipment 102 is a standalone system provided with a lidar, a radar, various kinds of sensors, a CPU, and a GPU.

The cooling system includes an electrical equipment controller 104 controlling an operating state of the electrical equipment 102, wherein the electrical equipment controller 104 receives an input of pressure variation data of a vehicle interior from a pressure sensor P1 sensing a pressure change of the vehicle interior, and receives an input of temperature variation data of the vehicle interior from a temperature sensor Ti sensing a temperature change of the vehicle interior.

The electrical equipment controller 104 sends a control signal to a main controller 600 provided in the vehicle so that a blowing mode of the vehicle is switched from an indoor air mode to an outdoor air mode before the electric compressor 500 is turned off.

According to embodiments of the present disclosure, the cooling of the electrical equipment provided in the self-driving car can be performed using the cooling water circulating between the chiller unit and the cooling object.

According to embodiments of the present disclosure, the cooling of the heat exchange unit and the cooling of the cooling object can be performed through the chiller unit in association with the electric compressor through sensing of the temperature and the pressure of the blowing air, and thus the cooling efficiency can be improved.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a diagram briefly illustrating the overall configuration of an electrical equipment cooling system for a vehicle according to an embodiment of the present disclosure;

FIG. 2 is a perspective view of an electrical equipment cooling system for a vehicle according to an embodiment of the present disclosure;

FIGS. 3 to 5 are perspective views illustrating internal configurations of an electrical equipment cooling system for a vehicle at various angles according to an embodiment of the present disclosure;

FIG. 6 is a diagram illustrating a vehicle electrical equipment cooling system mounted in a self-driving car in a state where blowing is performed in an indoor air mode according to an embodiment of the present disclosure;

FIG. 7 is a diagram illustrating a vehicle electrical equipment cooling system mounted in a self-driving car in a state where blowing is performed in an outdoor air mode according to an embodiment of the present disclosure;

FIG. 8 is a diagram illustrating a case where blowing air having passed through an interior of a casing moves to a cooling object according to an embodiment of the present disclosure; and

FIG. 9 is a diagram illustrating an electrical equipment controller, a main controller, and associated peripheral configurations according to an embodiment of the present disclosure.

### DESCRIPTION OF SPECIFIC EMBODIMENTS

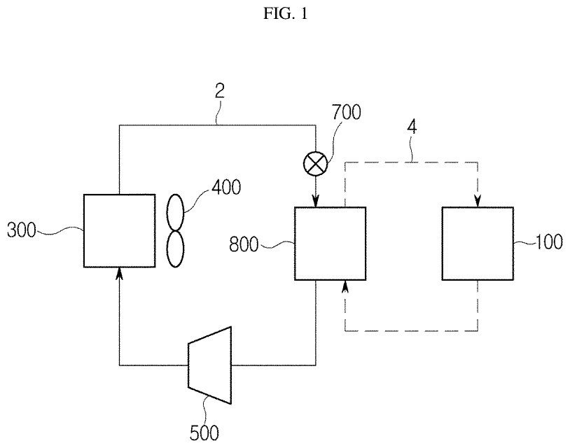

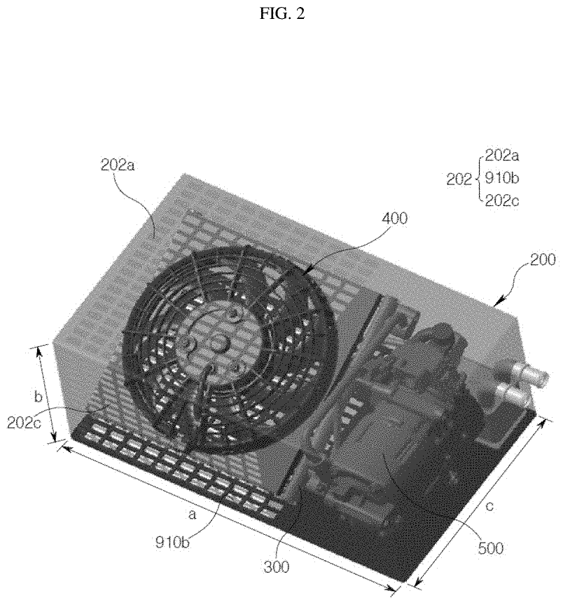

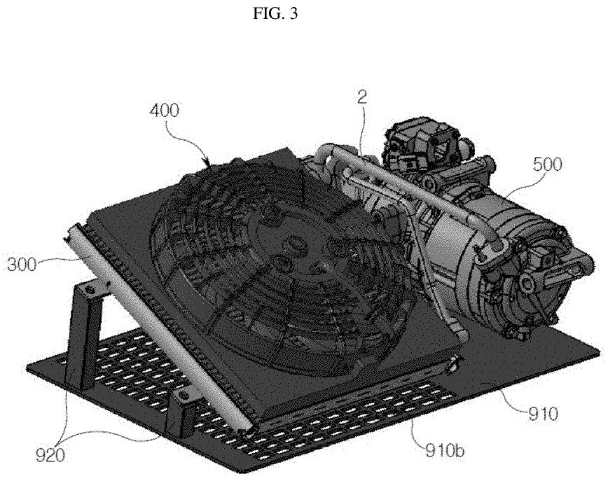

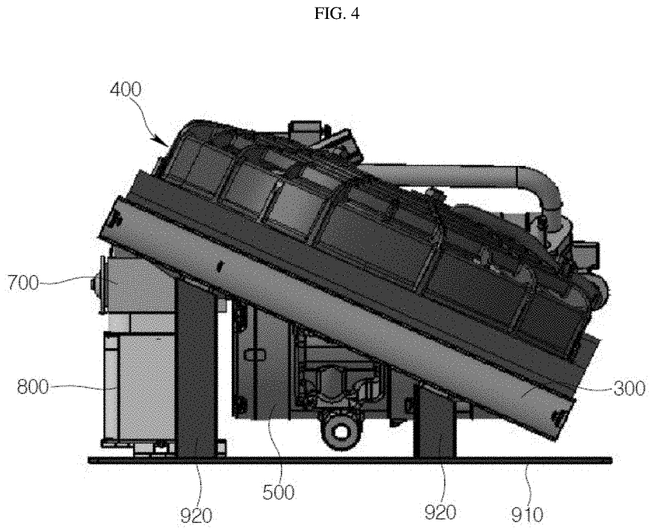

An electrical equipment cooling system for a vehicle according to an embodiment of the present disclosure will be described with reference to the accompanying drawings. FIG. 1 is a diagram briefly illustrating the overall configuration of an electrical equipment cooling system for a vehicle according to an embodiment of the present disclosure, FIG. 2 is a perspective view of an electrical equipment cooling system for a vehicle according to an embodiment of the present disclosure, and FIGS. 3 to 5 are perspective views illustrating internal configurations of an electrical equipment cooling system for a vehicle at various angles according to an embodiment of the present disclosure.

With reference to accompanying FIGS. 1 to 5, the present embodiment is to perform cooling of electrical equipment 102 of a cooling object 100 installed in a self-driving car 10 using a blowing mode of a vehicle interior.

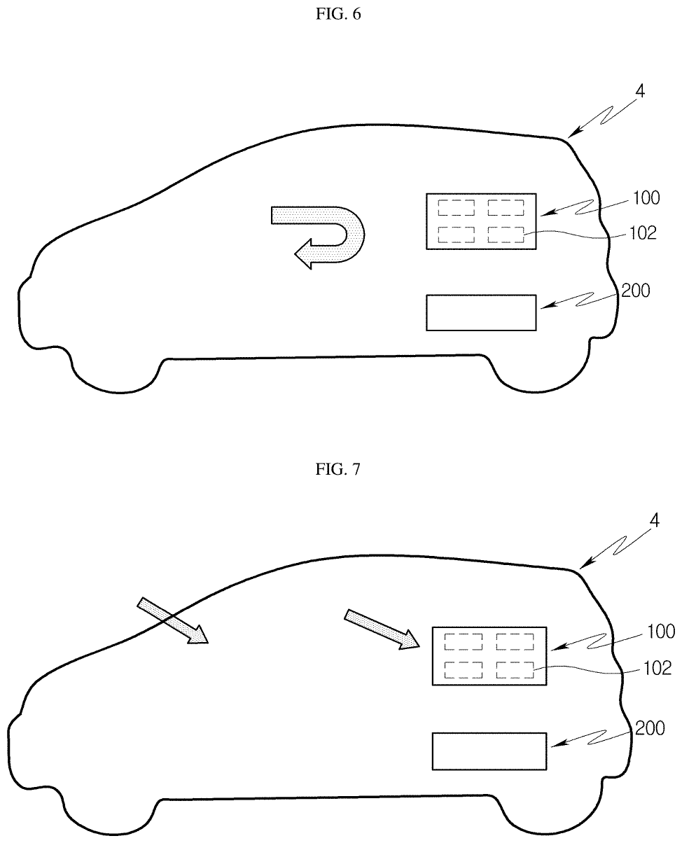

In particular, the self-driving car 10 (refer to FIG. 6) corresponds to a system which self-determines a driving path by sensing and processing external information and recognizing surrounding environments during driving even in case that a driver does not control a brake, a handle, or an acceleration pedal, and independently performs the driving using self-power. For example, unlike a driverless car that performs driving without a driver, the self-driving car means that a driver exists within the car, but does not take part in driving.

According to the present embodiment, a high-temperature and high-pressure refrigerant being compressed by an electric compressor 500 moves to a condenser 300 to be described later, and the refrigerant is cooled in the condenser 300 in an air-cooled manner by a fan unit 400 to be described later.

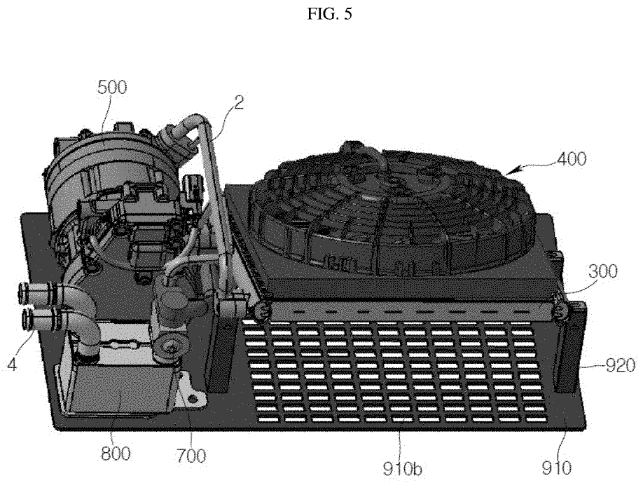

The refrigerant passes through an expansion valve 700 (refer to FIG. 5) along a refrigerant pipe 2 to be in a low-temperature and low-pressure state, and is provided to a chiller unit 800 to be described later. The chiller unit 800 is a kind of evaporator, and performs phase transition of the high-temperature and high-pressure liquid refrigerant before passing through the expansion valve 700 to the low-temperature and low-pressure gaseous refrigerant to supply the refrigerant to the electric compressor 500.

The above-described refrigerant repeatedly passes through the above-described components to perform the phase transition, and seeks cooling of the vehicle.

In addition, for driving convenience of a driver, the self-driving car is provided with the electrical equipment 102, and as an example of the electrical equipment 102, a standalone system provided with a lidar, a radar, various kinds of sensors, a CPU, and a GPU is used.

The lidar is an abbreviation of light detection and ranging, and is equal to a laser radar. The lidar may be considered as a radar developed using a laser beam having a property close to a radio wave.

The lidar may emit a pulsed laser light in the air, and may measure a distance or an atmospheric phenomenon using an emitted reflector or scatterer.

In particular, the self-driving car 10 is provided with various kinds of sensors and cameras to accurately grasp the surrounding situations, and enables the self-driving car 10 to safely drive through recognition of the surrounding environment of the lidar in two dimensions.

The radar is an abbreviation of radio detecting and ranging, and is a wireless monitoring device which can detect a distance, a direction, and an altitude of the car by emitting electromagnetic waves to the degree of microwaves (ultrahigh frequency waves, wavelength of 10 to 100 cm) toward front or side rear vehicles and receiving the electromagnetic waves being reflected from the vehicles.

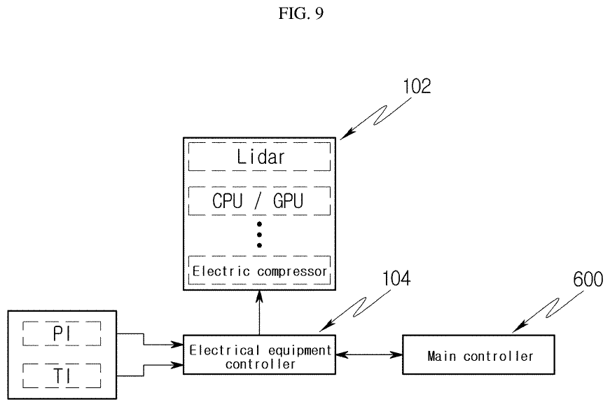

The lidar currently acquires data that is necessary for vehicle driving around the self-driving car 10, and the radar also transmits acquired data to an electrical equipment controller 104 to be described later (refer to FIG. 9).

The cooling object 100 is composed of a plurality of electrical equipment 102 provided therein for stable driving of the self-driving car 10, and is cooled by circulating cooling water through a cooling water pipe 4 connected to the chiller unit 800 so that a problem caused by the heating of the cooling object 100 being operated is minimized in case that the cooling object 100 is installed in the vehicle interior.

For this, the present embodiment includes an electric compressor 500 compressing and circulating a refrigerant, a condenser 300 condensing the compressed refrigerant, an expansion valve 700 throttling the condensed refrigerant, a chiller unit 800 performing heat exchange between the throttled refrigerant and the cooling water, and a fan unit 400 adjacently disposed in front of the condenser 300 and inhaling a running wind for condensing the compressed refrigerant. Further, the condenser 300 and the fan unit 400 are disposed to be tilted with respect to a direction in which the running wind is inhaled.

In particular, inside the casing 200, the condenser 300, the fan unit 400, the electric compressor 500, and the chiller unit 800 are configured to be packaged, and the cooling object 100 as described above is provided on an upper side of the casing 200. The condenser 300 is provided inside the casing 200 in which a vent grill 202 opened with a specific size to perform air movement is formed, and thus stable cooling is performed even if the operating cooling object 100 generates heat at high temperature.

In the present embodiment, the condenser 300 performs the cooling through the fan unit 400, and the cooling object 100 performs the cooling through the chiller unit 800, so that the stable driving and the cooling of the self-driving car 10 can be sought.

In the present embodiment, the cooling water pipe 4 is connected between the chiller unit 800 and the cooling object 100 to make fluid movement between them possible. As an example, if a low-temperature cooling water is supplied from the chiller unit 4 to the cooling object 100, the cooling of the cooling object 100 is performed.

Further, the cooling water is supplied to the chiller unit 800 as indicated by an arrow after the temperature of the cooling water is increased through the heat exchange with the cooling object 100 for a specific time, and performs the heat exchange with the low-temperature refrigerant. Thereafter, the cooling water is supplied again from the chiller unit 800 to the cooling object 100.

As described above, if the low-temperature cooling water continuously circulates in and moves to the cooling object 100 through the cooling water pipe 4, overheat due to the heating of the cooling object 100 can be prevented. In case that the vehicle indoor or outdoor air is maintained at high temperature especially in summer, the cooling is performed simultaneously with the operation of the electric compressor 500, and thus the stable operation of the electric compressor 500 can be maintained.

The casing 200 is provided with a bottom plate 910 located on an inner bottom surface of the casing 200 and a stand 920 having one end connected to the bottom plate 910 and the other ends extending toward the condenser 300 with different lengths, and the condenser 300 is disposed to be tilted by the stand 920.

As illustrated in the drawing, the condenser 300 is disposed to be tilted on one side by the stand 920 in a state where the condenser 300 is not in close contact with the bottom plate 910 but is spaced apart from the bottom plate 910. With reference to FIG. 3, the stand 920 provided at a corner location along the edge of the bottom plate 910 extends longer than the stand located on the center lower side, and thus in case of installing the condenser 300, the condenser 300 is disposed to be tilted on one side.

As described above, if the condenser 300 is disposed to be tilted, spaces in which running wind can flow are formed on upper and lower sides of the condenser 300, and the cooling effect of the condenser 300 can be improved using the spaces, thereby being advantageous in cooling efficiency.

The condenser 300 is located to face the fan unit 400, and has a corresponding size. The condenser 300 is in the form as illustrated in the drawing. The condenser 300 is disposed to be tilted at any one angle selected among tilting angles of 15° to 30°. The condenser 300 is tilted at the above-described angle in consideration of the size and the disposal relationship of the casing 200, and as an example, in the present embodiment, the condenser 300 is disposed at the above-described angle to maintain the maximally low height of the casing 200.

In this case, the surrounding layout of the casing 200 and the degree of freedom of the design of the surrounding components can be improved, and thus more stable space disposal becomes possible.

In the casing 200, a first gap space Si is formed in an upwardly spaced location between an inner bottom surface of the casing 200 and the condenser 300, and a second gap space S2 is formed between an inner upper surface of the casing 200 and the fan unit 400.

The first gap space Si and the second gap space S2 provide spaces for seeking stable movement of the blowing air and improving the cooling efficiency of the electric equipment 102.

Forming the first gap space S1 (between the inner bottom surface of the casing 200 and the condenser 300) may be more advantageous than disposal of the condenser 300 in close contact with the inner bottom of the casing 100 in movement of the blowing air, and sufficient space for heat exchange of the condenser 300 can be secured.

As the fan unit 400, a sirocco fan is used, but other types of fans can be used. As the fan unit 400, an axial fan is used, and is obliquely installed inside the casing 200 in a manner that it is disposed to be tilted at an acute angle that is smaller than a right angle.

As described above, if the fan unit 400 is obliquely disposed, it is more advantageous in inflow of the blowing air, and in case that air inflow is performed through the first vent grill 202a opened on an upper surface of the casing 200, stable air inflow is performed without partial clogging or stagnation.

In the present embodiment, the casing 200 is formed in a cuboidal shape, and as an example, a length corresponding to a height b extends to be shorter than a length corresponding to a width a or a length corresponding to a depth c, and thus the casing 200 is formed in a plate shape and has a compact configuration.

If the casing 200 is formed as described above, the height b projects low, and interference with the surrounding layout and surrounding components is prevented to improve the degree of freedom of design of a designer.

The vent grill 202 includes a first vent grill 202a opened on an upper surface of the casing 200, a second vent grill 910b opened on the bottom plate 910, and a third vent grill 202c opened on a front surface of the casing 200.

The first vent grill 202a is opened in the form as illustrated in the drawing for inflow of the blowing air, but it may have a different form or a different arrangement.

The first vent grill 202a and the second vent grill 910b are formed to face each other with a corresponding size, and thus if the running wind flows in through the first vent grill 202a, it can stably move through the second vent grill 910b to improve the movement stability.

The second vent grill 910b is formed with the first vent grill 202a for the movement of the blowing air, and may be formed with a size different from the size of the first vent grill 202a. As an example, the second vent grill 910b may be formed to be larger than the opening size of the first vent grill 202a.

Since the second vent grill 910b should provide the blowing air toward the electrical equipment 102, it is advantageous that the second vent grill 910b is opened to be larger than the first vent grill 202a, and thus the second vent grill 910b is configured as above.

The third vent grill 202c is provided for movement of the blowing air to the front surface of the casing 200. Referring to FIG. 5, the chiller unit 800 is formed in a cuboidal shape with a specific size, and a plurality of cooling water pipes 4 are provided on an upper side thereof. The cooling water pipe 4 may be provided with a separate thermal insulator (not illustrated) on an outside thereof to prevent a heat loss.

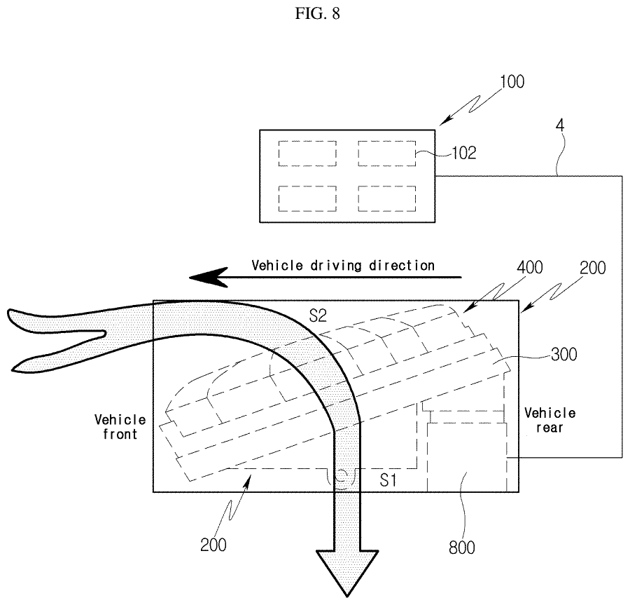

Referring to the accompanying FIGS. 6 to 8, according to the present embodiment, the cooling of the condenser 300 can be performed using the running wind flowing into the interior during driving of the vehicle or using the blowing air being discharged into the interior when the mode is switched to the indoor air mode.

Further, according to the present embodiment, the casing 200 is formed to have a structure that is advantageous to the inflow of the running wind or the blowing air flowing into the interior while the vehicle is driven. Further, efficient cooling of the electrical equipment 102 can be sought through disposal of the condenser 300 and the fan unit 400 disposed in the casing 200.

For example, in case that the self-driving car 10 is driven in an indoor air mode, as the air that is necessary to cool the electrical equipment 102, the blowing air discharged into the interior flows in through the first vent grill 202a as described above, and is supplied to the condenser 300 through the fan unit 400.

In case of driving in an outdoor air mode, the self-driving car 10 is partially supplied with the air that is necessary to cool the condenser 300 through an extractor grill (not illustrated). As an example, the upper surface of the casing 200 is located adjacent to the extractor grill provided in the vehicle. In this case, the outdoor air that is necessary to cool the condenser 300 can be supplied through the extractor grill.

In this case, if the temperature of the outdoor air is lower than the indoor temperature, the blowing air that is necessary to cool the condenser 300 is not dependent on only the blowing air discharged into the interior, but a part of the outdoor air may flow into the interior of the casing 200 to be used as the air that is necessary for cooling.

Accordingly, the condenser 300 can be prevented from being overheated even in case of the temperature increase due to the high-temperature refrigerant, and thus error or trouble can be prevented from occurring even if the self-driving car 10 is driven for a long time.

In case that the self-driving car 10 is in an outdoor air mode, together with the above-described embodiment, a part of the blowing air flowing into the vehicle interior is cooled by the air being cooled as passing through the vent grill 202 formed on the casing 200.

Accordingly, the self-driving car 10 can efficiently perform the cooling of the condenser 300 in accordance with the indoor air mode and the outdoor air mode.

Referring to the accompanying FIG. 9, if the lidar, radar, various kinds of sensors, CPU, and GPU are simultaneously operated, the processing speed of the electrical equipment controller 104 for processing plural pieces of data may deteriorate as the self-heating temperature is increased up to the temperature before and after 90° C.

In this case, an error may occur in the electrical equipment 102 due to the self-heating, and this may cause an accident of the self-driving car 10. However, in the present embodiment, since the chiller unit 800 is provided to cool the electrical equipment 102, a stable cooling can be performed.

The electrical equipment controller 104 is provided to perform the cooling of the electrical equipment 102 more efficiently and to perform a control in accordance with the temperature and the pressure of the interior of the self-driving car 10, and operates in association with the main controller 600.

The electrical equipment controller 104 is provided to control the operating state of the electrical equipment 102. As an example, the electrical equipment controller 104 receives an input of pressure variation data of the vehicle interior from a pressure sensor P1 sensing a pressure change of the vehicle interior, and receives an input of temperature variation data of the vehicle interior from a temperature sensor Ti sensing a temperature change of the vehicle interior.

The pressure sensor P1 senses the pressure being generated when the blowing air moves through the fan unit 400 provided in the casing 200, and transmits the currently sensed pressure data to the electrical equipment controller 104.

The temperature sensor Ti senses the temperature of the blowing air flowing into the casing 200, and transmits the currently sensed temperature data to the electrical equipment controller 104.

The electrical equipment controller 104 receives data sensed by the pressure sensor P1 and the temperature sensor T1, and transmits the corresponding data to the main controller 600.

The main controller 600 receives an input of the data being transmitted by the electrical equipment controller 104, and controls the blowing mode of the vehicle to be switched from the indoor air mode to the outdoor air mode before the electric compressor 500 is turned off.

For example, in winter seasons, the blowing air being heated up to a specific temperature for air heating is supplied to the interior of the self-driving car 10 in the indoor air mode. If the temperature is increased due to the heating of the electrical equipment 102 while the self-driving car 10 is driven for a long time, the blowing mode is switched from the indoor air mode to the outdoor air mode.

In the outdoor air mode, an outdoor air that is relatively colder than the indoor air flows into the interior, and the cooling is performed as the low-temperature blowing air is supplied to the condenser 300 through the vent grill 202.

Accordingly, the stable cooling of the electrical equipment 102 is performed through the blowing air mode conversion, and even in case that the self-driving car 10 is driven for a long time, a normal driving continues without error or malfunction occurrence.

For efficient operation of the electric compressor 500 according to the present embodiment, the electric compressor 500 is turned off in case that the indoor temperature of the self-driving car 10 is equal to or lower than a reference value, and it is turned on in case that the indoor temperature is higher than the reference value.

If the electric compressor 500 is turned off, the blowing air being blown into the interior flows into the inside of the casing 200 to perform the cooling, and if the temperature of the blowing air is increased, the electric compressor 500 is turned on to supply the refrigerant whose phase is changed to the low temperature to the chiller unit 800, so that the cooling water moves through the above-described cooling water pipe 4 to perform the cooling of the cooling object 100.

Although preferred embodiments of the present disclosure have been described for illustrative purposes, the present disclosure is not limited by them, and those of ordinary skill in the art will appreciate that various modifications, additions and substitutions are possible, without departing from the scope and spirit of the disclosure as disclosed in the accompanying claims.

1. An electrical equipment cooling system for a vehicle, comprising:
an electric compressor compressing and circulating a refrigerant;
a condenser condensing the compressed refrigerant;
an expansion valve throttling the condensed refrigerant;
a chiller unit performing heat exchange between the throttled refrigerant and a cooling water; and
a fan unit adjacently disposed in front of the condenser and inhaling a running wind for condensing the compressed refrigerant,
wherein the condenser and the fan unit are disposed to be tilted with respect to a direction in which the running wind is inhaled.

2. The system of claim 1, wherein the condenser is provided inside a casing in which a vent grill opened with a specific size to perform air movement is formed.

3. The system of claim 1, wherein the casing is formed in a cuboidal shape in which a length corresponding to a height b extends to be shorter than a length corresponding to a width a or a length corresponding to a depth c.

4. The system of claim 1, comprising a cooling water pipe forming a loop that is branched from the chiller unit and is recycled to the chiller unit after passing through a cooling object in order to cool the cooling object composed of a plurality of electrical equipment being self-heated with a specific temperature, and providing a passage through which the cooling water moves.

5. The system of claim 4, wherein the electrical equipment is provided in a self-driving car.

6. The system of claim 1, wherein the casing is provided with:
a bottom plate located on an inner bottom surface of the casing; and
a stand having one end connected to the bottom plate and the other ends extending toward the condenser with different lengths,
wherein the condenser is disposed to be tilted by the stand.

7. The system of claim 2, wherein the vent grill comprises:
a first vent grill opened on an upper surface of the casing;
a second vent grill opened on the bottom plate; and
a third vent grill opened on a front surface of the casing.

8. The system of claim 7, wherein the first vent grill and the second vent grill are formed to face each other with a corresponding size.

9. The system of claim 7, wherein the second vent grill is formed to be larger than an opening size of the first vent grill.

10. The system of claim 1, wherein the condenser is located to face the fan unit, and has a corresponding size.

11. The system of claim 1, comprising:
a first gap space S1 formed in an upwardly spaced location between an inner bottom surface of the casing and the condenser; and
a second gap space S2 formed between an inner upper surface of the casing and the fan unit.

12. The system of claim 1, wherein an upper surface of the casing is located adjacent to an extractor grill provided in the vehicle.

13. The system of claim 4, wherein the electrical equipment is a standalone system provided with a lidar, a radar, various kinds of sensors, a CPU, and a GPU.

14. The system of claim 4, comprising an electrical equipment controller controlling an operating state of the electrical equipment,
wherein the electrical equipment controller receives an input of pressure variation data of a vehicle interior from a pressure sensor P1 sensing a pressure change of the vehicle interior, and receives an input of temperature variation data of the vehicle interior from a temperature sensor T1 sensing a temperature change of the vehicle interior.

15. The system of claim 14, wherein the electrical equipment controller sends a control signal to a main controller provided in the vehicle so that a blowing mode of the vehicle is switched from an indoor air mode to an outdoor air mode before the electric compressor is turned off.
